(19) United States
(12) Patent Application Publication
(10) Pub. No.: US 2019/0214327 A1
(43) Pub. Date: Jul. 11, 2019

(54) THERMAL CONDUCTION DEVICES AND METHODS FOR EMBEDDED ELECTRONIC DEVICES

(71) Applicants: Sonja Koller, Regensburg (DE); Bernd Waidhas, Pettendorf (DE); Thomas Ort, Veitsbronn (DE); Andreas Wolter, Regensburg (DE)

(72) Inventors: Sonja Koller, Regensburg (DE); Bernd Waidhas, Pettendorf (DE); Thomas Ort, Veitsbronn (DE); Andreas Wolter, Regensburg (DE)

(21) Appl. No.: 15/866,810

(22) Filed: Jan. 10, 2018

(51) Int. Cl. H01L 23/373; H01L 21/56; H01L 23/498; H01L 25/065; H01L 23/00

(52) U.S. Cl. CPC H01L 23/3733; H01L 21/56; H01L 24/49; H01L 25/0657; H01L 23/49816

(57) ABSTRACT

A semiconductor device includes a semiconductor die that is coupled to a substrate. A mold compound encapsulates the semiconductor die and one or more passages are in the mold compound between a backside of the mold compound and an electrically non-active region of the first semiconductor die. A thermal conductor material within the one or more of the passages.

### TECHNICAL FIELD

Embodiments described herein generally relate to thermal management of electronic devices.

### BACKGROUND

Manufacturing components for computing devices involves rigorous manufacturing processes that involve placing, or packaging numerous electric materials onto a substrate to create electrical components such as semiconductors, integrated circuits (ICs), chip sets, and the like. The electrical material is often referred to as a die that can be electrically connected to the substrate in any conventional manner, including but not limited to, wire bonding and flip chip bonding. Such electrical components are then utilized in or as memory devices, modern processors, such as a central processing unit (CPU), a graphics processing unit (GPU), advanced processing unit (APU), or combinations thereof, and the like.

When such components are manufactured, numerous electrical and mechanical considerations must be taken into account to create a viable end product. Such considerations include, but are not limited to, physical damage, mechanical vibrations, thermal properties, electrical properties such as electric and magnetic fields, electrostatic discharge, and the like. Packaging refers to the process of encapsulating, or protecting the electrical material in regard to the substrate in order to account for these and other electrical and mechanical properties.

Through advances in packaging technologies stacked die packages have been created. Stacked die packages provide for a first die that is electrically connected to the substrate through typical means, and a second die that is electrically connected to the first die through conventional means including wire bonding and flip chip bonding. Such packages provide for improved spatial configurations, electrical operation, and more efficient manufacturing processes, but also still present challenges related to improving mechanical and electrical characterizes while presenting efficient manufacturing processes.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 shows a side schematic view of a package assembly in accordance with some example embodiments.

FIG. 2 shows a side schematic view of a package assembly in accordance with some example embodiments.

FIG. 3 shows a top schematic view of a package assembly in accordance with some example embodiments.

FIG. 4 shows a side schematic view of a package assembly in accordance with some example embodiments.

FIG. 5 shows a side schematic view of a package assembly in accordance with some example embodiments.

FIG. 6 shows a side schematic view of a package assembly in accordance with some example embodiments.

FIG. 7 shows a side schematic view of a package assembly in accordance with some example embodiments.

FIG. 8 shows a side schematic view of a package assembly in accordance with some example embodiments.

FIG. 9 shows a side schematic view of a package assembly in accordance with some example embodiments.

FIG. 10 shows a side schematic view of a package assembly in accordance with some example embodiments.

FIG. 11 shows a flow diagram of a method of forming a package assembly in accordance with some example embodiments.

FIG. 12 shows a system that may incorporate aligning systems and methods, in accordance with some example embodiments.

### DETAILED DESCRIPTION

Die packages present numerous challenges to manufacturers in efficiently manufacturing reliable packages that withstand the rigors of everyday use. The electrical components on the substrate operate with current running through the components, thus generating a significant amount of heat that may be detrimental to the proper functioning of the electrical components if not properly dissipated. Components of any package are made from materials that have threshold temperatures for operating at maximum reliability or performance limits. Thus, as heat is generated by the components, the heat must be conveyed away from the components at a rate to keep all regions within a package below such threshold temperature to avoid premature material failures, power leakages, and reduction in overall performance of the electrical component.

In an effort to improve such heat conveyance, often a mold compound of the package conveys the heat away from the electrical components to outside the package. Thus, one way of facilitating the heat transfer is to select a mold with a high thermal conductivity, typically in the range between 3-6 Watts per Meter Kelvin at 25° C. (W/m-K). The mold compound encapsulates the stacked die system providing protection for the electrical components. Currently, the mold material is selected based on many competing characteristics. These include, but are not limited to thermal properties, adhesion to silicon or other package materials, coefficient of thermal expansion (CTE), Young's modulus, cohesive strength, cost of materials, or the like. Unfortunately, a manufacturer must choose between these competing properties when selecting the mold such that choosing a material with better thermal conduction properties results in deficiencies in other areas of the mold.

Another way in which heat properties are improved within a package is by utilizing a heat spreader that is attached to the package. Typically, the heat spreader interfaces with the mold compound and heat is conveyed from areas within the package to the heat spreader. While, the heat spreader itself is efficient at conveying heat from the package, often the interface material between the heat spreader and electronic components within the package provides poor thermal conductivity. In addition, on occasion, the use of a heat spreader is impractical for use within the package. In such packages, the mold compound remains the main method of conveying heat from within areas of the package. This results in numerous shortcomings within the package.

By utilizing additional manufacturing steps to reinforce the mold compound with material having high thermal conductivity, a manufacturer may chose a mold based on other characteristics such as adhesion to silicon or other package materials, coefficient of thermal expansion, Young's modulus, cohesive strength, or the like to improve the package. In particular, the stacked die packages provided overcome deficiencies because during the manufacturing process, after the mold compound cures, a laser is used to drill a plurality of perforations, or passages, in pre-selected locations of the mold compound. The preselected locations are chosen based on both heat properties of the package and determinations regarding mechanical balancing of the package.

These perforations are then filled using a material having a high thermal conductivity. Thus, the mold compound continues to provide protection for the electrical components within the package while the fill material having a high thermal conductivity improves thermal characteristics and other such mechanical characteristics within the package. This process and resulting packages minimize warpage and operation temperatures, prevent premature failure of components, and maximize performance of the packages.

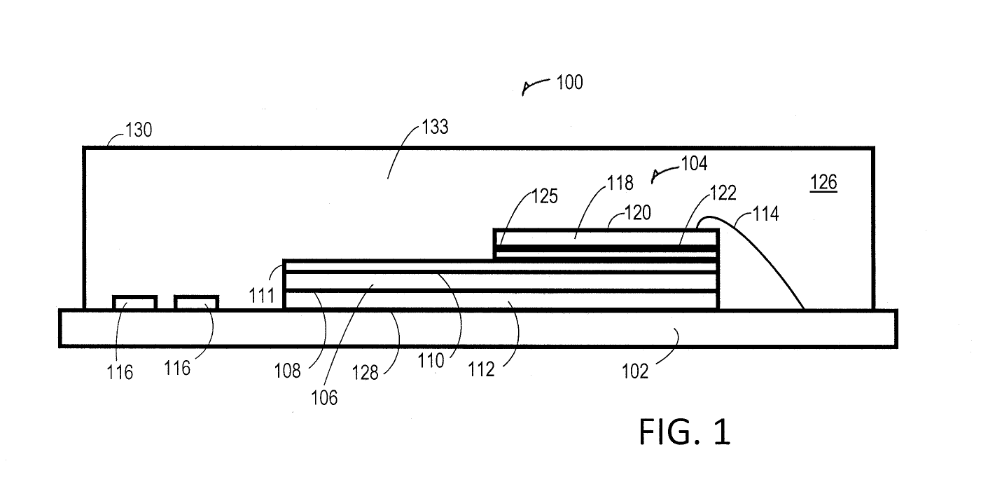

FIGS. 1-5 show example packages in numerous stages of a process of manufacturing a package 100 through the methodologies contained herein. While described and illustrated in the figures with reference to a single package, typically multiple packages are manufactured and singulated. This includes examples with three packages with a single substrate singulated into three separate packages.

This example presents a stacked die package. In an initial stage as illustrated in FIG. 1 a stacked die package 100 is assembled. The stacked die package 100 in the example of FIGS. 1-5 includes a substrate 102 with electrical components 104 coupled to the substrate 102.

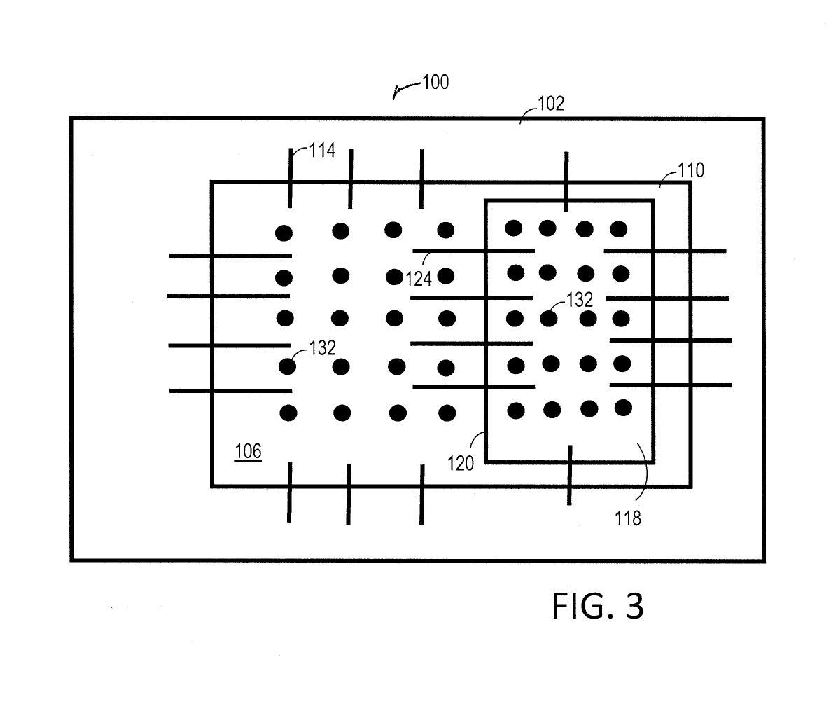

The electrical components 104 include a bottom semiconductor die 106 having a backside 108 and top side 110. Optionally, a die backside metallization layer 111 may be formed on the top side 110 of the bottom semiconductor die 106 by sputtering or any other known method. The backside 108 of the bottom semiconductor die 106 is coupled to the substrate 102 through an interconnect layer 112 that in one embodiment is a metallization layer. With an interconnect layer provided on its backside 108, the bottom semiconductor die 106 may be coupled to the substrate 102 through any known method. This includes the metallization layer for flip chip dies, passivation openings over metal on non-flip chip dies, and solder mask openings on the substrate 102 over metal. Optionally, exposed metal may be wetted with solder through printing or bumping to enhance connections. Additionally, coupling is made through wire elements 114 as a result of wire bonding as illustrated in FIG. 3.

The electrical components 104 also may include substrate pad elements 116 as illustrated in FIGS. 1-2 and 4-5. The substrate pad elements 116 are coupled to the substrate 102 in spaced relation to the bottom semiconductor die 106. The substrate pad elements 116 are coupled to one or more of the electrical components 104 in any manner including flip chip bonding and wire bonding and in this example present a different height than the bottom semiconductor die 106.

A top semiconductor die 118 having a top side 120 and backside 122 is stacked on top of and is coupled to the bottom semiconductor die 106. The top semiconductor die 118 is coupled in any manner, including but not limited to flip chip bonding, or through a wire element 114 or 124 as a result of wire bonding as illustrated in FIGS. 1-5. Specifically, wire elements 124 extend from the top semiconductor die 118 to the topside 110 of the bottom semiconductor die 106 (FIG. 3) and wire elements 114 extend from the top semiconductor die 118 to the substrate 102 (FIGS. 1-5) to provide the electrical connection. The stacked top semiconductor die 118 in this example is attached to the topside 110 of the bottom semiconductor die 106 with a die attach film 125.

The top semiconductor die 118 may be one of many side-by-side spaced apart top semiconductor dies stacked on the bottom semiconductor die 106. The top semiconductor die 118 in one embodiment is positioned off center of the bottom semiconductor die 106 to facilitate connection of the wire bonding in embodiments as shown in FIGS. 1-5. In the embodiments of FIGS. 1-5, the stacked die arrangement not only provides electrical components 104 of differing heights, but also consequently causes imbalance across the substrate 102.

In the embodiments of FIGS. 1-5, a mold compound 126 extends over the substrate 102 to encapsulate the bottom semiconductor die 106, pad elements 116, and top semiconductor die 118. The mold compound 126 extends from a backside 128 to a top side 130. The mold compound 126 is chosen by a manufacturer based on characteristics, including but not limited to adhesion to silicon or other package materials, coefficient of thermal expansion, Young's modulus, cohesive strength, or the like. The mold compound 126 is injected over the electronic components 104 on the substrate 102 and cured.

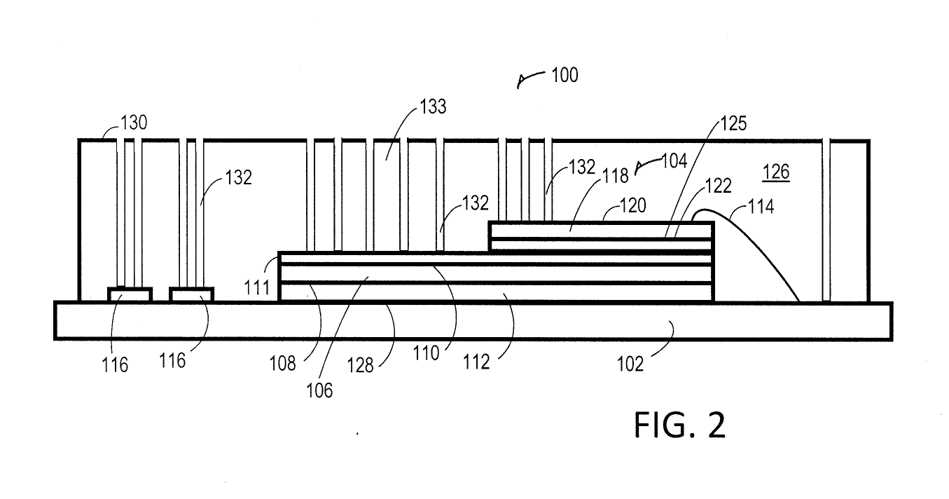

FIG. 2 illustrates the manufacturing process after the mold compound 126 cures. A laser drills an array of passages 132, or perforations, through the top side 130 of the mold compound 126 within preselected areas of the mold compound 126. This includes from the backside 128 of the mold compound 126 through non-active regions 133 of the semiconductor dies 106, 118 and substrate 102. The laser is configured to provide an array of passages 132 in any manner. The laser is also configured to drill through the mold compound 126 and metallization layer 111. Drilling includes using a plurality of lasers, a patterned beam, mechanically moving the laser to predetermined locations, mechanically moving or rotating the package assembly 100, or the like.

The laser is of any type capable of drilling the passages 132 described. Such lasers include, but are not limited to CO2 lasers, Nd:YAG lasers, copper vapor lasers, excimer lasers, and the like. Such lasers include use of UV, visible light, and IR wavelengths, including a range from 0.1 μm to 11 μm. The laser thus produces a laser beam having sufficient energy to melt or drill each passage 132 in the mold compound 126, or portion of the package where the passage 132 is to be drilled.

The diameter of the passages 132 or perforations are selected based on requirements of the package 100. Such diameters range is between 5 μm to 500 μm with a local density having a minimum pitch of approximately 1.5 times the diameter. Similarly, the depth and placement of each passage 132 may vary. Typically, an array of passages are evenly spaced over a topside of either the bottom semiconductor die, top semiconductor die, substrate, or combination thereof.

The location of the passages 132 are selected based on multiple considerations. As an example, passages 132 are disposed through the mold compound 126 perpendicular to the top sides of the electrical components 104 or substrate 102, including the substrate 102, bottom semiconductor die 106, the pad elements 116, and top semiconductor die 118. In this manner, the passages 132 provide a pathway from the substrate 102, bottom semiconductor die 106, pad elements 116, or top semiconductor die 118 to outside the mold compound 126. Passages 132 are also positioned to avoid drilling the wire elements 114, 124 of either the bottom semiconductor die 106 or the top semiconductor die 118. Still, as a result of the size and shape of the drilled passages 132, the passages are able to be positioned in close proximity to the wire elements 114, 124.

In another example, the amount of passages 132 formed and location within the mold compound 126 is based on the mechanical properties, including, but not limited to elasticity, coefficient of thermal expansion, density, and the like, of the bottom semiconductor die 106, pad elements 116, top semiconductor die 118, and mold compound 126, and the location of these components on the substrate 102 about a center axis 134 of the substrate 102. Specifically, in example packages where the bottom semiconductor die 106 or top semiconductor die 118 are not centered about the center axis 134, the material filled into the passages 120 and location of the passages 120 about the center axis 134 are used to balance around the center axis 134. In this manner, a balanced package is formed reducing warpage during operation.

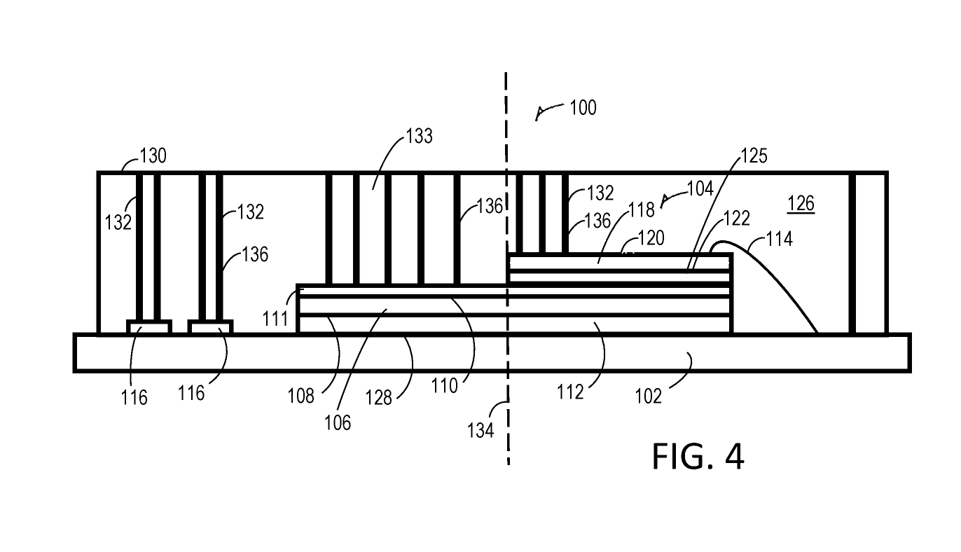

FIG. 4 illustrates a package after a filling operation. At this stage, the thermal conductor material filling 136 is dispensed into the passages 132. In an example, the passages are filled with the thermal conductor material using a screen or stencil printing device. In another example, the passages 132 are plated by galvanic metallization to fill the passages 132 with thermal conductor material. Alternatively, the passages 132 are filled with thermal conductor material through a chemical deposition. In one embodiment, copper is the thermal conductor material provided through chemical deposition. Additionally, optionally, after filling of the passages 132 the mold compound topside 130 can undergo a planarizing process. Thus, numerous methods may be used to fill the passages 132 disposed within the package 100.

The thermal conductor material filling 136 is selected to have a thermal conductivity that is greater than the thermal conductivity of the mold compound 126. In one example, the mold compound 126 has a thermal conductivity in a range between 0.5-5 W/m-K while the thermal conductor material filling has a thermal conductivity of at least 15 W/m-K and in a range between 15-1500 W/m-K. Thus, in any given embodiment, the thermal conductivity of the thermal conductor material filling 136 may be between ten times to up to a thousand times greater than the thermal conductivity of the mold material. Such thermal conductor material filling 136 may be a graphite composite, a solder material, a paste comprised of epoxy and metallic particles, or the like. The metallic particles of the epoxy may include, but are not limited to copper (Cu), silver (Ag), copper coated silver, or the like. In particular, pre-selection includes not only a determination of thermal properties of the thermal conductor material filling 136, but additionally, density of the thermal conductor material filling 136 such that the thermal conductor material filling 136 may be used to balance the thermo-mechanical composition of the package 100 about the center axis 134 of the substrate 102 to minimize negative effects from warpage of the package 100.

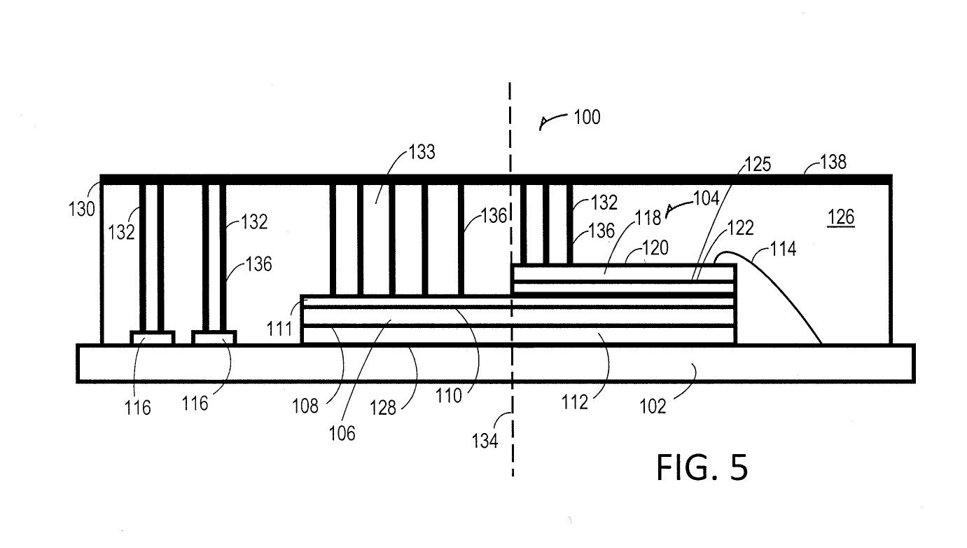

FIG. 5 illustrates an example of an optional process during the manufacturing process related to FIGS. 1-4. In this example, a support layer 138 such as a passivation layer is secured to the mold compound 126, engaging and interfacing with both the mold compound 126 and the thermal conductor material filling 136 filled in the plurality of passages 132. In one example the passivation layer 138 is a tape that provides additional protection for the entire package. To the extent the passages 132 and fill material weaken the integrity of the package 100, by selecting a mold material with increased strength and providing the passivation layer 138, the overall strength of the package 100 and its resilience to corrosion is enhanced.

The tables below show a comparison of a stacked die package with thermal conductor material filling 136 in an array of passages 132 through the mold compound 126 as manufactured in the examples of FIGS. 1-2, 4-5, to a similar stacked die package with a mold compound encapsulation without using the thermal conductor material filling within an array of passages in the mold compound. Table 1 below shows the junction to ambient thermal resistance JA [K/W] (Kelvin/Watt).

TABLE 1

| | UC1 | UC2 |
|---|---|---|
| FC Mold Compound | 23.5 | 21.8 |
| With Filled Mold Perforations | 22.8 | 20.8 |

Table 2 meanwhile provides the time to 85° C. in minutes for the same stacked die packages.

TABLE 2

| | UC1 | UC2 |
|---|---|---|
| FC Mold Compound | 3.5 | 7.7 |
| With Filled Mold Perforations | 5 | 10.9 |

As can be seen from the tables and graph, for two separate power consumption scenarios (trail use-cases UC1, UC2) the thermal resistance of the stacked die package 100 of FIGS. 1-2 and 4-5 using thermal conductor material in the passages was significantly less than the thermal resistance of the identical stacked die arrangement with no alterations made to the mold compound. As shown in Table 2, as a result of the improved thermal conduction of the package, in the first trial UC1 the stacked die package 100 took a minute and a half longer to reach 85° C. than the stacked die package with no alterations to the package.

In the second trial UC2 an additional three minutes passed before 85° C. was reached in the package 100 of FIGS. 1-2, 4-5. Consequently, thermal based deficiencies such as thermal fatigue, malfunction, performance throttling, (leakage) power increase and the like are minimized.

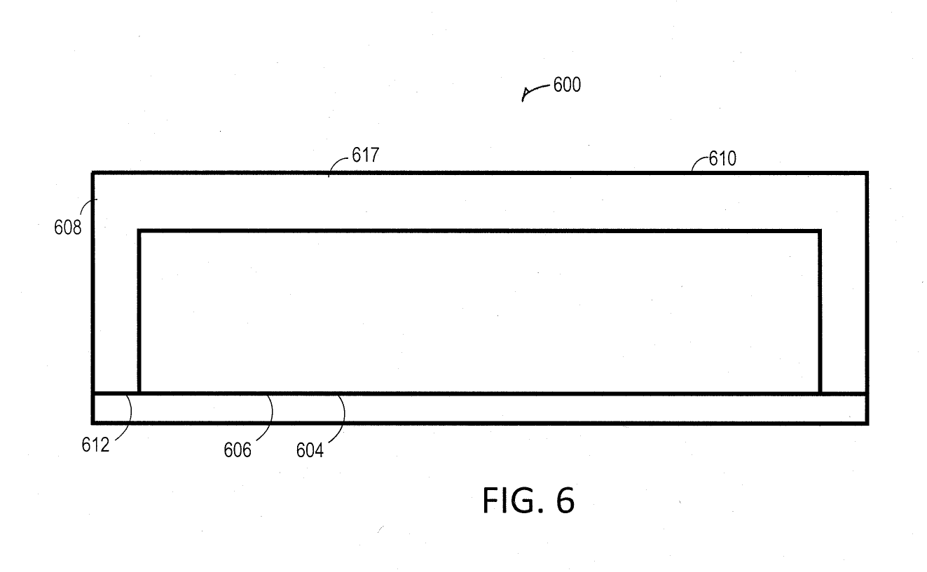

FIGS. 6-10 illustrate another example package 600 and show an example stage by stage process of manufacturing the package 600 through the methodologies contained herein. This example presents an embedded wafer level ball grid array (eWLB package). In an initial step, as illustrated in FIG. 6, eWLB wafers 600 are assembled, including a semiconductor die 604 and built in redistribution layers (RDL). The semiconductor dies 604 are encapsulated by a mold compound 608 that extends to a backside 606 of the semiconductor die 604.

The mold compound 608 is applied and cured in any manner as discussed in relation the FIGS. 1-5. The mold compound 608 has a topside 610 and backside 612 and is selected based on characteristics of the mold material, including but not limited to adhesion to silicon or other package materials, coefficient of thermal expansion, Young's modulus, cohesive strength, or the like.

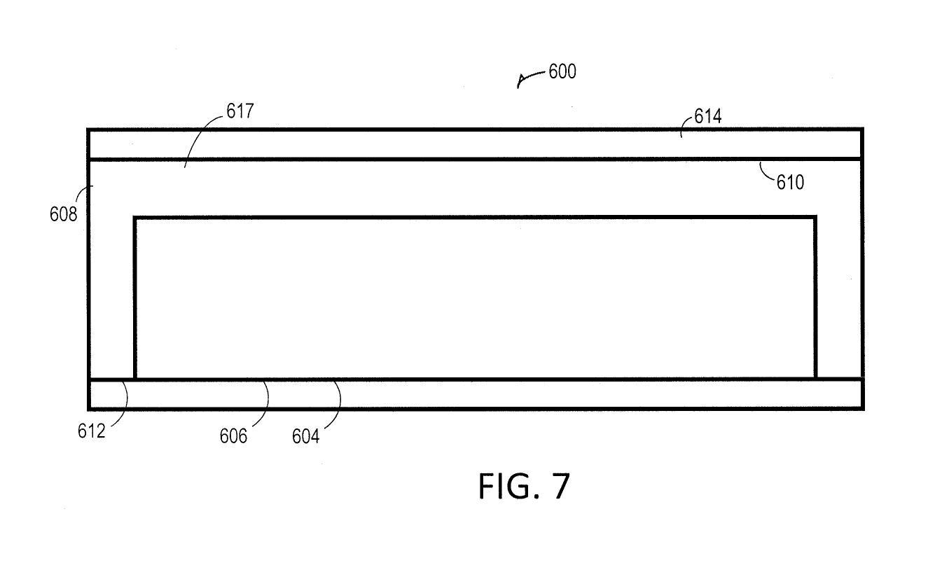

Optionally, as provided in FIG. 7, a heat spreading layer 614 is secured to a topside 610 of the mold compound 608. In one example, the heat spreading layer 614 is a metallization layer that is metal foil attached to the top side 610 of the mold compound 608.

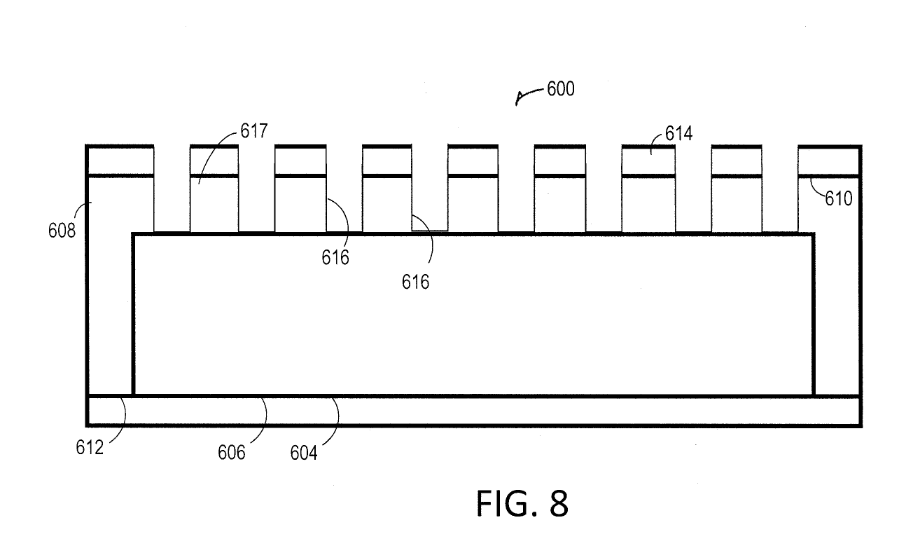

FIG. 8 illustrates the manufacturing process after the mold compound 608 cures. A laser drills an array of passages 616 within preselected areas of the mold compound 608 through the topside 610 of the mold compound. This includes extending from the backside 612 of the mold compound 608 through non-active regions 617 of the semiconductor die 604. The laser thus also drills through the heat spreading layer 614 and through the mold compound 608 to the semiconductor die 604.

The laser is of any type and drills the passages 616 in any manner as previously described in regard to FIGS. 1-5. Specifically, the laser in one example includes, but is not limited to CO2 lasers, Nd:YAG lasers, copper vapor lasers, excimer lasers, and the like. Such lasers include use of UV, visible light, and IR wavelengths, including a range from 0.1 μm to 11 μm.

In this manner, the laser drills the passages 616 at the pre-selected locations and at pre-selected depths through the package 600. This includes drilling passages 616 through the mold compound 608 and the heat spreading layer 614. The laser thus produces a laser beam having sufficient energy to melt or drill each passage 616 in the mold compound 608, heat spreading layer 614, or other portion of the package where the passage 616 is to be drilled. The passages 616 provide a pathway through the mold compound 608 for heat to be conveyed through the package 600.

The diameter and depth of the passages 616 or perforations are selected based on requirements of the package. Such diameters range is between 5 μm to 500 μm with a local density having a minimum pitch of approximately 1.5 times the diameter. Similarly, the depth and placement of each passage 616 may vary, or alternatively be of equal depth extending through the mold compound 608 and heat spreading layer 614 to the topside of the package 600. In the embodiment of FIGS. 6-10 the passages are relatively thick compared to the depth as compared to the embodiment of FIGS. 1-5.

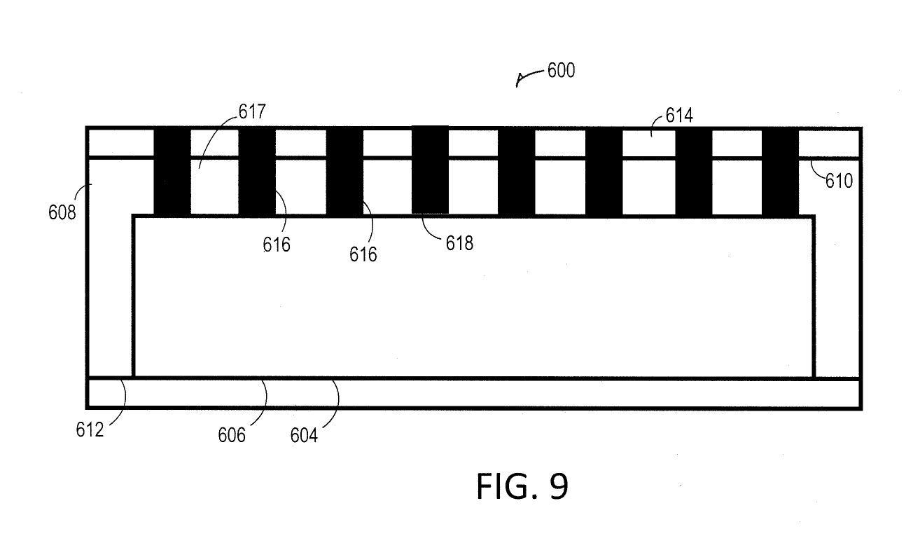

FIG. 9 illustrates a filling operation during manufacturing of the package. Thermal conductor material filling 618 is dispensed into the passages 616. In an example, the passages 616 are filled with the thermal conductor material filling 618 by a screen or stencil printing device. In another example, the passages 616 are plated by galvanic metallization to fill the passages 616 with thermal conductor material. Alternatively, the passages 616 are filled with thermal conductor material through a chemical deposition. In one embodiment, the copper is the thermal conductor material provided through chemical deposition. Thus, numerous methods may be used to fill the passages 616 disposed within the package 600.

The thermal conductor material filling 618 is selected to have a thermal conductivity that is greater than the thermal conductivity of the mold compound 608. In one example, the mold compound 608 has a thermal conductivity in a range between 0.5-5 W/m-K while the thermal conductor material filling 618 has a thermal conductivity of at least 15 W/m-K and in a range between 15-1500 W/m-K. Thus, in any given embodiment, the thermal conductivity of the thermal conductor material filling 618 may be between ten times to up to a thousand hundred times greater than the thermal conductivity of the mold material. Such thermal conductor material filling 618 may be a graphite composite, a solder material, a paste comprised of epoxy and metallic particles, or the like. The metallic particles of the epoxy may include, but are not limited to copper (Cu), silver (Ag), copper coated silver, or the like. In particular, pre-selection includes not only a determination of thermal properties of the thermal conductor material filling 618, but additionally, density of the thermal conductor material filling 618 such that the thermal conductor material filling 618 may be used to balance the thermo-mechanical composition of the package 600 about the center axis 620 of the package 600 to minimize negative effects from warpage of the package 600.

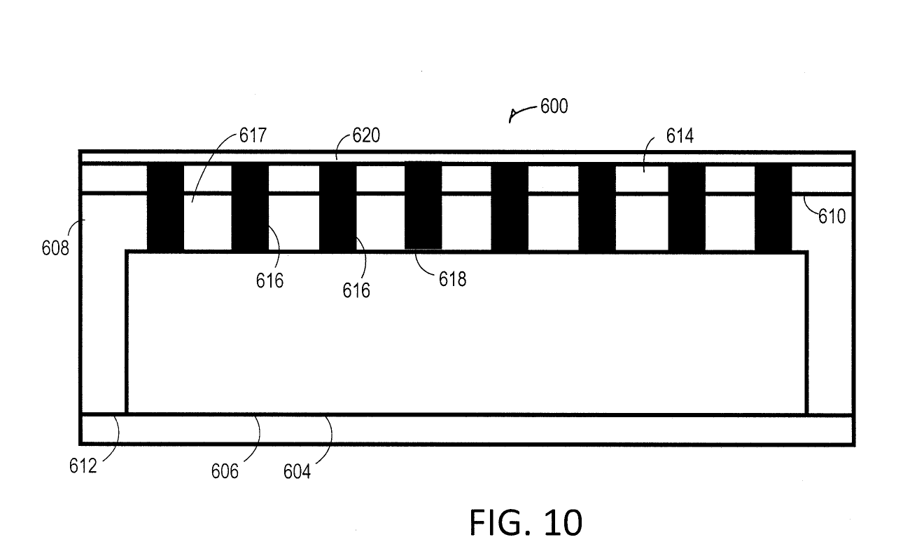

FIG. 10 illustrates the package 600 in one embodiment where optionally, a support layer 620 is applied to the top of the package. In one example, a planarizing process is applied to the topside of the package, while alternatively, a passivation layer is applied to the topside of the package. In one example the support layer 620 is a tape that provides additional protection for the entire package. To the extent the passages 616 and fill material weaken the integrity of the package 600, by selecting a mold material with increased strength and providing the support layer 620, the overall strength of the package 600 and its resilience to corrosion is enhanced.

The set of tables below illustrate analytical estimates of different thermal properties of for an eWLB package 600 formed as described in FIGS. 6-10 with drilled passages and thermal conductor material filling versus a similar eWLB that only utilizes a typical mold and a similar eWLB that utilizes a mold with increased thermal conductance, but not with passages and the thermal conductor material. For the estimate, the pitch of each passage 616 is approximately 60 μm, the diameter approximately 40 μm. The semiconductor die thickness is approximately 440 μm and mold cap thickness approximately 520 μm.

TABLE 3

| | W/(m*K) |
|---|---|
| Standard Mold Compound eWLB | 1.7 |
| Mold with Increased Thermal Conductance | 3.0 |
| Thermal Conductor Material Filler | 60.0 |
| Standard Mold Perforated and Filled | 22.1 |

In the above table 3, thermal conductivity through the plane is provided in W/(mm*K). The thermal conductor material filler used is shown to have a thermal conductivity of 6.00E-02 W/(mm*K). Thus, when used within the passages, averaged thermal conductivity to the package topside is greatly increased to 22.1 W/(m*K) compared to the thermal conductivity of the same package using a standard mold (1.7 W/(m*K)) and the same package using an increased thermal conductance mold material (3.0 W/(m*K)).

The table 4 below illustrates the thermal resistance of the mold cap of the eWLB package of FIGS. 6-10 again compared to the mold cap of the same package using a standard mold, and a mold with increased thermal conductance. As illustrated, the thermal resistance to the package topside is significantly reduced within the package of FIGS. 6-10.

TABLE 4

| | mm\hat{ }2 K/W |
|---|---|
| Standard Mold Compound | 47.06 |
| Mold with Increased Thermal Conductance | 26.67 |
| Standard Mold Perforated and Filled | 3.63 |

The table 5 below illustrates the thermal resistance from junction to package topside, again comparing the eWLB package of FIGS. 6-10 to similar eWLB packages using a standard mold and a high conductance mold. In the table calculations were made looking at different chip areas to show the improvement for different sized chips. Chip sizes were 15 mm\hat{ }2, 25 mm\hat{ }2, and 35 mm\hat{ }2.

TABLE 5

| Chip Area [mm\hat{ }2] | 15 | 25 | 35 |
|---|---|---|---|
| Standard Mold Compound [K/W] | 3.39 | 2.03 | 1.45 |
| Mold with Increased Thermal Conductance[K/W] | 2.03 | 1.22 | 0.87 |
| Mold Perforated and Filled [K/W] | 0.49 | 0.3 | 0.21 |

The table 5 above shows utilizing the eWLB package of FIGS. 6-10 again greatly reduces thermal resistance to the package topside compared to a standard mold and even when a package includes a mold material with increased thermal conductivity. Thus, the package of FIGS. 6-10 provides improved thermal properties over these other packages.

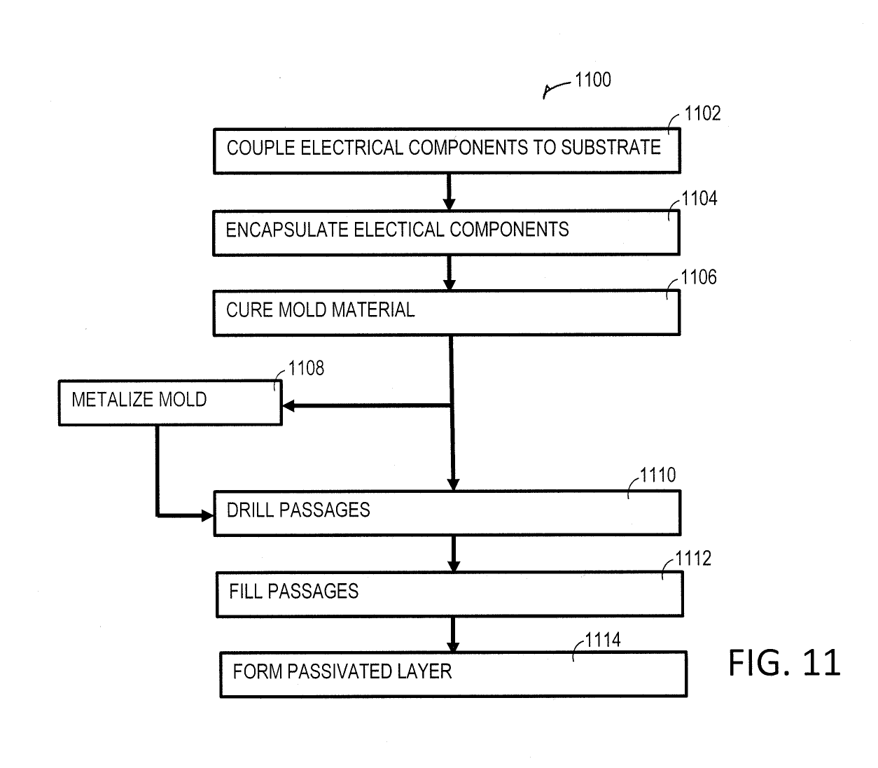

FIG. 11 illustrates one example of a method of manufacturing a package 1100. At 1102, the electrical components are coupled to a substrate. These electrical components may include one or more bottom semiconductor dies, pad elements, top semiconductor dies, or the like. The non-active side of the semiconductor optionally are metalized. Coupling includes any manufacturing process, including but is not limited to flip chip bonding, wire bonding, and the like. Alternatively, the package 1100 includes an embedded wafer level ball grid array with chips including redistribution layers.

At 1104, a mold material encapsulates the electrical components. The mold compound is applied automatically through any known techniques including injection molding. The mold material used is selected based on any number of characteristics, including but not limited to adhesion to silicon or other package materials, coefficient of thermal expansion, Young's modulus, cohesive strength, or the like. At 1106, the mold material is cured to form the mold compound that encapsulates the electrical components.

At 1108, optionally, a mold compound of the package is metalized to form a heat spreading layer. In one example, a metal foil is secured to the topside of the mold compound encapsulating a chip of a eWLB.

At 1110, an array of passages are drilled into the mold compound. The passages extend from a surface of the mold compound to a surface of a substrate, an electrical component, or chip. Drilling is provided both through the mold compound and also through any metallization or heat spreading layer attached during the manufacturing process. In one embodiment, the array of passages are substantially evenly spread across the substrate, bottom semiconductor die, top semiconductor die, chip, or the like.

In one example drilling is done by a laser emitting a beam of size and shape desired. Such diameters range is between 5 μm to 500 μm with a local density having a minimum pitch of approximately 1.5 times the diameter. The laser in one example includes, but is not limited to a CO2 laser, Nd:YAG laser, copper vapor laser, excimer laser, and the like. Such lasers include use of UV, visible light, and IR wavelengths, including a range from 0.1 μm to 11 μm. In one example, the laser emits a patterned beam to provide the plurality of passages in spaced relation across the mold. Alternatively, laser is moved and positioned to preselected positions to drill. To that end, depths of the passages may vary depending of the position in the package including depending on the height of the electrical components within the package.

At 1112, a thermal conductor material filling is dispensed into the array of passages that has a thermal conductivity that is greater than the thermal conductivity of the mold material. In one example the injected material is a paste that comprises an epoxy and metallic particles. In another example the material is solder material. In one example, the mold compound has a thermal conductivity in a range between 0.5-5 W/m-K while the thermal conductor material filling has a thermal conductivity of at least 15 W/m-K and in a range between 15-1500 W/m-K. Thus, in any given embodiment, the thermal conductivity of the thermal conductor material filling may be between ten times and a hundred times greater than the thermal conductivity of the mold material. The material may be applied or injected with passages using printing, dispensing, plating by galvanic metallization, or chemical deposition of a metal such as copper as described in all previous embodiments and examples.

At 1114, optionally, a passivated layer is formed on the surface of the mold compound where drilling was performed. The passivated layer in one example is a tape that seals the plurality of passages and provides improved heat spreading from the material within the passages.

The methodology 1100 presented provides advantages because the material in the filled passages thermally couple the package backside to a silicon substrate that has good thermal conductive properties. In particular, silicon has thermal conduction of 120 W/m-K.

The methodology is beneficial when non-uniform height profiles exist of silicon within the package due to die stacking as provided in example package 100, or when side-by-side dies of different heights is provided. Similarly, advantages are presented in packages with wire bonded dies, because the passages or perforations are provided locally to all regions not spanned by wire bonds as provided in the example packages of FIG. 1-5. The methodology and resulting packages are also beneficial for when exposed die packages are not possible. This includes eWLB type packages as provided in the example of package 600.

In addition, the methodology 1100 may be utilized to level asymmetries in unbalanced packages, such as the stacked die arrangements of FIGS. 1-5. Specifically, the passages are located in areas of the package and fill material selected to balance the thermo-mechanical composition along a central axis of a package. Thus, warpage of the package is minimized.

The methodology 1100 and resulting packaging also present materials that make better thermal contact to the semiconductor dies than internal heat spreaders. Specifically, heat spreaders require attachment by thin films of poor thermal conductivity instead of extending to the silicon of the substrate.

Finally, as a result of the methodology, mold material is optimized for mechanical properties such as adhesion to silicon, adhesion to other package materials, coefficient of thermal expansion, Young's modulus, cohesive strength, or the like. Consequently, filled mold multi-perforations or passages allow the benefit of improving mechanical characteristics of the mold compound encapsulation, while also improving the heat transfer to the backside of the package. Specifically, material properties of the mold compound and the passage filler are optimized independently for each respective purpose. Therefore, an improved methodology and resulting packages are presented.

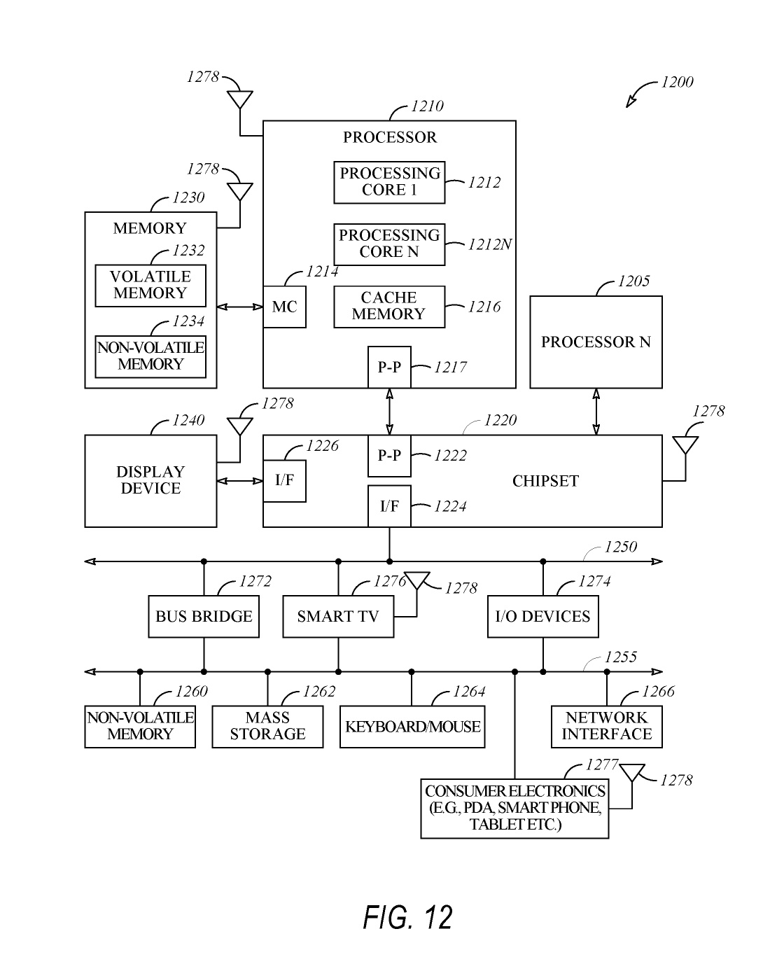

FIG. 12 illustrates a system level diagram, depicting an example of an electronic device (e.g., system) that may include thermal management devices, techniques, and/or methods described above. For example, devices may include CPUs/processors, chipsets, graphics devices, wireless devices, multi-chip/3D package including CPU with other devices, and memory. FIG. 12 may also illustrate a system level diagram of an electronic device used to execute examples of the methods described above. In one embodiment, system 1200 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 1200 is a system on a chip (SOC) system.

In one embodiment, processor 1210 has one or more processor cores 1212 and 1212N, where 1212N represents the Nth processor core inside processor 1210 where N is a positive integer. In one embodiment, system 1200 includes multiple processors including 1210 and 1205, where processor 1205 has logic similar or identical to the logic of processor 1210. In some embodiments, processing core 1212 includes, but is not limited to, pre-fetch logic to fetch instructions, decode logic to decode the instructions, execution logic to execute instructions and the like. In some embodiments, processor 1210 has a cache memory 1216 to cache instructions and/or data for system 1200. Cache memory 1216 may be organized into a hierarchal structure including one or more levels of cache memory.

In some embodiments, processor 1210 includes a memory controller 1214, which is operable to perform functions that enable the processor 1210 to access and communicate with memory 1230 that includes a volatile memory 1232 and/or a non-volatile memory 1234. In some embodiments, processor 1210 is coupled with memory 1230 and chipset 1220. Processor 1210 may also be coupled to a wireless antenna 1278 to communicate with any device configured to transmit and/or receive wireless signals. In one embodiment, an interface for wireless antenna 1278 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 1232 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 1234 includes, but is not limited to, flash memory, phase change memory (PCM), read-only memory (ROM), electrically erasable programmable read-only memory (EEPROM), or any other type of non-volatile memory device.

Memory 1230 stores information and instructions to be executed by processor 1210. In one embodiment, memory 1230 may also store temporary variables or other intermediate information while processor 1210 is executing instructions. In the illustrated embodiment, chipset 1220 connects with processor 1210 via Point-to-Point (PtP or P-P) interfaces 1217 and 1222. Chipset 1220 enables processor 1210 to connect to other elements in system 1200. In some embodiments of the example system, interfaces 1217 and 1222 operate in accordance with a PtP communication protocol such as the Intel® QuickPath Interconnect (QPI) or the like. In other embodiments, a different interconnect may be used.

In some embodiments, chipset 1220 is operable to communicate with processor 1210, 1205N, display device 1240, and other devices, including a bus bridge 1272, a smart TV 1276, I/O devices 1274, nonvolatile memory 1260, a storage medium (such as one or more mass storage devices) 1262, a keyboard/mouse 1264, a network interface 1266, and various forms of consumer electronics 1277 (such as a PDA, smart phone, tablet etc.), etc. In one embodiment, chipset 1220 couples with these devices through an interface 1224. Chipset 1220 may also be coupled to a wireless antenna 1278 to communicate with any device configured to transmit and/or receive wireless signals.

Chipset 1220 connects to display device 1240 via interface 1226. Display 1240 may be, for example, a liquid crystal display (LCD), a light emitting diode (LED) array, an organic light emitting diode (OLED) array, or any other form of visual display device. In some embodiments of the example system, processor 1210 and chipset 1220 are merged into a single SOC. In addition, chipset 1220 connects to one or more buses 1250 and 1255 that interconnect various system elements, such as I/O devices 1274, nonvolatile memory 1260, storage medium 1262, a keyboard/mouse 1264, and network interface 1266. Buses 1250 and 1255 may be interconnected together via a bus bridge 1272.

In one embodiment, mass storage device 1262 includes, but is not limited to, a solid-state drive, a hard disk drive, a universal serial bus flash memory drive, or any other form of computer data storage medium. In one embodiment, network interface 1266 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 12 are depicted as separate blocks within the system 1200, the functions performed by some of these blocks may be integrated within a single semiconductor circuit or may be implemented using two or more separate integrated circuits. For example, although cache memory 1216 is depicted as a separate block within processor 1210, cache memory 1216 (or selected aspects of 1216) can be incorporated into processor core 1212.

### Various Notes & Examples

Example 1 is a semiconductor device, comprising: a first semiconductor die coupled to a substrate; a mold compound encapsulating the semiconductor die; one or more passages in the mold compound between a backside of the mold compound and an electrically non-active region of the first semiconductor die; and a thermal conductor material filling the one or more passages.

Example 2 is a semiconductor device further comprising: a metalization layer coupled to the backside of the first semiconductor die.

In Example 3, the subject matter of any one or more of Examples 1-2 optionally include wire bonds from the first semiconductor die coupled to the topside of the substrate.

In Example 4, the subject matter of any one or more of Examples 1-3 optionally include a second semiconductor die coupled to the first semiconductor die having a height that is different than a height of the first semiconductor die; and one or more passages in the mold compound between the backside of the mold compound and an electrically non-active region of the second semiconductor die.

In Example 5, the subject matter of any one or more of Examples 1-4 optionally include wherein the one or more passages are an array of passages substantially evenly spaced over the first semiconductor die.

In Example 6, the subject matter of any one or more of Examples 1-5 optionally include a passivation layer extending over the filled one or more passages.

Example 7 is a semiconductor device, comprising: a first semiconductor die coupled to a substrate; a second semiconductor die coupled to a backside of the first semiconductor die; a mold compound encapsulating the first and second semiconductor dies; one or more passages in the mold compound between a backside of the mold compound and an electrically non-active region of either the first or second semiconductor dies; and a thermal conductor material filling the one or more passages.

In Example 8, the subject matter of Example 7 optionally includes wherein the first semiconductor die is a processor and the second semiconductor die is a memory.

In Example 9, the subject matter of any one or more of Examples 7-8 optionally include wire bonds coupled between the second semiconductor die and the substrate.

In Example 10, the subject matter of any one or more of Examples 7-9 optionally include wherein the one or more passages in the mold compound are between the backside of the mold compound and the electrically non-active region of the first semiconductor die and between the backside of the mold compound and the electrically non-active region of the second semiconductor die.

In Example 11, the subject matter of any one or more of Examples 7-10 optionally include one or more passages in the mold between a backside of the mold compound and an electrically non-active region of the substrate.

Example 12 is a method forming a semiconductor device, the method comprising: encapsulating a semiconductor die coupled to a substrate using a mold compound; forming one or more passages in the mold compound between a backside of the mold compound and an electrically non-active region of the semiconductor die; and filling the one or more passages with a thermal conductor material.

In Example 13, the subject matter of Example 12 optionally includes wherein forming the one or more passages in the mold compound between the backside of the mold compound and an electrically non-active region of the semiconductor die includes laser drilling the one or more passages in the mold compound.

In Example 14, the subject matter of any one or more of Examples 12-13 optionally include wherein encapsulating the semiconductor die coupled to the substrate using the mold compound includes encapsulating a semiconductor die of an artificial wafer.

In Example 15, the subject matter of any one or more of Examples 12-14 optionally include wherein filling the one or more passages with a thermal conductor material includes pressing a paste into the one or more passages in the mold compound.

In Example 16, the subject matter of any one or more of Examples 12-15 optionally include wherein filling the one or more passages with a thermal conductor material includes electroplating the thermal conductor material into the one or more passages in the mold compound.

In Example 17, the subject matter of any one or more of Examples 12-16 optionally include wherein filling the one or more passages with a thermal conductor material includes chemical deposition of the thermal conductor material into the one or more passages in the mold compound.

In Example 18, the subject matter of Example 17 optionally includes wherein the thermal conductor material is copper.

Each of these non-limiting examples may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

1. A semiconductor device, comprising:
a semiconductor die coupled to a substrate;
a mold compound encapsulating the semiconductor die;
one or more passages in the mold compound between a topside of the mold compound and the semiconductor die; and
a thermal conductor material within the one or more passages.

2. The semiconductor device further comprising:
a metallization layer coupled to a backside of the semiconductor die.

3. The semiconductor device of claim 1 further comprising:
wire bonds from the semiconductor die coupled to a topside of the substrate.

4. The semiconductor device of claim 1 further comprising:
wherein the semiconductor die is a first semiconductor die, the device further comprising a second semiconductor die coupled to the first semiconductor die having a height that is different than a height of the first semiconductor die; and
one or more passages in the mold compound between the topside of the mold compound and the second semiconductor die.

5. The semiconductor device of claim 1 wherein the one or more passages are an array of passages substantially evenly spaced over the semiconductor die.

6. The semiconductor device of claim 1 further comprising:
a passivation layer extending over the one or more passages.

7. The semiconductor device of claim 1 wherein the one or more passages extend through an electrically non-active region of the semiconductor die.

8. A semiconductor device, comprising:
a first semiconductor die coupled to a substrate;
a second semiconductor die coupled to a backside of the first semiconductor die;
a mold compound encapsulating the first and second semiconductor dies;
one or more passages in the mold compound between a backside of the mold compound and an electrically non-active region of either the first or second semiconductor dies; and
a thermal conductor material within the one or more passages.

9. The semiconductor device of claim 8 wherein the first semiconductor die is a processor and the second semiconductor die is a memory.

10. The semiconductor device of claim 8 further comprising:
wire bonds coupled between the second semiconductor die and the substrate.

11. The semiconductor device of claim 8 wherein the one or more passages in the mold compound are between the backside of the mold compound and the electrically non-active region of the first semiconductor die and between the backside of the mold compound and the electrically non-active region of the second semiconductor die.

12. The semiconductor device of claim 8 further comprising:
one or more passages in the mold between a backside of the mold compound and an electrically non-active region of the substrate.

13-19. (canceled)
